(19) United States
(12) Patent Application Publication
(10) Pub. No.: US 2008/0310237 A1
(43) Pub. Date: Dec. 18, 2008

(54) CMOS Compatible Single-Poly Non-Volatile Memory

(75) Inventors: Steve X. Zhou, Boise, ID (US); Daniel D. Li, Highland, CA (US)

Correspondence Address: PERKINS COIE LLP, P.O. BOX 1208, SEATTLE, WA, 98111-1208, US

(73) Assignee: Nantronics Semiconductor. Inc., San Ramon, CA (US)

(21) Appl. No.: 11/764,736

(22) Filed: Jun. 18, 2007

(51) Int. Cl. G11C 11/34

(52) U.S. Cl. 365/185.29

(57) ABSTRACT

The present invention teaches a single-poly non-volatile memory cell which is compatible with the CMOS process, uses lower voltages for operating, and is more reliable in program, read, or erase operation. The single-poly non-volatile memory cell in accordance with the present invention comprises a program transistor with a program terminal; a sensing transistor with a sensing terminal; and an erase transistor with an erase terminal, wherein the sensing transistor shares a floating gate with the program transistor and the erase transistor. By employing the present invention, significant cost advantages in feature-rich semiconductor products, such as System-on-Chip (SoC) design, compared to conventional dual-poly floating gate embedded Flash memory are provided.

### TECHNICAL FIELD

The present invention relates to non-volatile memory (NVM), and more particularly, to an NVM which is fully compatible with industry standard CMOS process, with very little or no extra cost added.

### BACKGROUND ARTS

NVM is now widely used for a variety of applications, since it may store information without continuously applied electric power, and by applying appropriate voltages, it can be programmed or re-programmed (erased). Such a memory may provide a basic operating system or microcode for a logic device, such as a processor. A kind of NVM, embedded NVM in a CMOS device, allows a single chip produced by a manufacturer to be configured for various applications, and/or allows a single device to be configured by a user for different applications. Programming of the embedded NVM is typically done by downloading code from an external source, such as a computer.

However, many NVM processes require multiple layers of poly-silicon, while many conventional CMOS processes require only a single layer of poly-silicon. In order to embed this kind of NVM into a CMOS device, several additional processing steps are required. These additional processing steps result in increased processing time, higher cost of manufacturing, increased possibility of defects, and in turn result in lower yields. To address this problem, repair circuit regions on the die are included in some circuit designs in order to compensate for the reduced device yield. But valuable areas on the die are consumed by these repair circuits, further increasing the cost of manufacturing.

Currently, ‘single poly-silicon’ NVM devices, which are more easily compatible with standard CMOS process flow, have been proposed. Several different single poly-silicon memory devices have been proposed. For example, more information about the single poly-silicon NVM may be found in U.S. Pat. No. 5,990,512 and U.S. Pat. No. 6,747,308.

NVM technology would be significantly benefited from NVM cells manufactured with the advantages of using a single poly-silicon layer. For it may be compatible with CMOS process, the improvement with significant advantages includes, but not limited to, reductions in costs, cycle times, defects and the capability to include more memory cells within a given area in a die. Single poly-silicon NVM often finds its usage in the field of embedded memory, such as embedded non-volatile memory in the mixed-mode circuit and micro-controller.

However, single poly NVM nowadays still has some disadvantages to be improved. First, the existing single poly NVM demands a relatively high voltage, for example a high couple well voltage, to perform program and erase operations. The types of single-poly NVM cells that require high program/erase voltages are undesirable for at least two reasons. Firstly, because of the operation voltage much higher than the supplied voltage Vcc, it presents challenges to the reliability of the tunneling oxide with a thickness of tens of Angstrom (Å). Additionally, the higher voltages require higher degrees of isolation, such as field oxide isolation, that consumes additional die area. Secondly, it may be difficult to generate such a high voltage on a chip using charge-transfer voltage, and additional high-voltage components and associated circuits are needed. Several other problems arise in the art associated with the operation of NVMs. Some single-poly memory cells are difficult to be reliably programmed, read, or erased, while others degrade after a relatively few number of programming cycles.

For these reasons, there is a need for a NVM which is compatible with the CMOS process, uses lower voltages for operating, and is more reliable in program, read, or erase operation.

### SUMMARY OF THE INVENTION

One aspect of the present invention teaches an NVM which is fully compatible with industry standard CMOS process, such as provided by semiconductor foundry companies. In some cases, the NVM is provided with very little or no extra cost added. This provides significant cost advantages in feature-rich semiconductor products, such as System-on-Chip (SoC) design, compared to conventional dual-poly floating gate embedded Flash memory. Furthermore, there is no impact on transistor performance in logic, I/O and analog circuitries. Therefore, standard design libraries can be used without any modification. This greatly reduces technology development cycle and time-to-market.

According to one aspect of the present invention, a single-poly non-volatile memory cell is provided, which comprises a program transistor with a program terminal; a sensing transistor with a sensing terminal; and an erase transistor with an erase terminal, wherein the sensing transistor shares a floating gate with the program transistor and the erase transistor. The potential on the shared floating gate is capacitively coupled from the program terminal, the erase terminal, and the sensing terminal.

To further lower the erase voltage, according to one embodiment of the present invention, the gate area of the erase transistor is much smaller than that of the program transistor and that of the sensing transistor, respectively.

In the present invention, the program transistor, the sensing transistor and the erase transistor may be PMOSFETs, and each of the program transistor, the sensing transistor and the erase transistor may reside in a separate NWELL. In addition, the program transistor, the sensing transistor and the erase transistor of the single-poly non-volatile memory cell may have a substantially same gate oxide thickness in the range of 60-80 Å. The non-volatile memory cell in accordance with the present invention may be constructed with single poly-silicon.

According to another aspect of the present invention, a single-poly non-volatile storage device is provided, which comprises a plurality of cells, each cell comprising a program transistor with a program terminal, a sensing transistor with a sensing terminal, and an erase transistor with an erase terminal, wherein the sensing transistor shares a floating gate with the program transistor and the erase transistor. The potential on the shared floating gate is capacitively coupled from the program terminal, the erase terminal, and the sensing terminal.

To further lower the erase voltage, according to one embodiment of the present invention, the gate area of the erase transistor is much smaller than that of the program transistor and that of the sensing transistor, respectively. In the present invention, the program transistor, the sensing transistor and the erase transistor may be PMOSFETs, and each of the program transistor, the sensing transistor and the erase transistor may reside in a separate NWELL. In addition, the program transistor, the sensing transistor and the erase transistor of the single-poly non-volatile memory cell may have a substantially same gate oxide thickness in the range of 60-80 Å. The non-volatile memory in accordance with the present invention may be constructed with single poly-silicon.

The single-poly non-volatile storage device further comprises a program mechanism; an erase mechanism; and a read mechanism, wherein the program mechanism functions by applying a first voltage on the program terminal, wherein the first voltage is not higher than 5V; the erase mechanism functions by applying a second voltage on the erase terminal, wherein the second voltage is not higher than 7V; and the read mechanism functions without any external high voltage supply.

In one embodiment of the present invention, the program mechanism functions by Channel Hot Electron (CHE) Injection, and the erase mechanism functions by Fowler-Nordheim (FN) Tunneling.

### DESCRIPTION OF THE DRAWINGS

In order to understand the manner in which examples of the present invention are obtained, a more particular description of various examples of the invention briefly described above will be rendered by reference to the appended drawings. Understanding that these drawings depict only typical examples of the invention that are not necessarily drawn to scale and are not therefore to be considered to be limited of its scope, the examples of the invention will be described and explained with additional specificity and detail through the use of the accompanying drawings, in which:

FIG. 1 is a chart showing an NVM Cell Structure in accordance with the present invention;

FIG. 2 is a schematic diagram showing the key capacitance components of the NVM cell in accordance with the present invention;

FIG. 3 is a simplified top view layout of the NVM cell in accordance with the present invention;

FIG. 4 is a cross-sectional view of the NVM cell in accordance with the present invention;

FIG. 5a is a cross-sectional view of the program element of the NVM cell in accordance with the present invention, which shows the impact ionization and the electron injection in the gate;

FIG. 5b is a band diagram representation of the high energy electrons due to the impact ionization which may surmount SiO₂ barrier and is injected into the gate; and

FIG. 5c is a typical current to voltage plot in a program operation.

### DETAILED EMBODIMENTS

Whereas many alterations and modifications of the present invention will become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims which in themselves recite only those features regarded as the invention.

In this description and claims, the terms “coupled” and “connected”, along with their derivatives, may be used. It should be understood that these terms are not intended as synonyms for each other. Rather, in particular embodiments, “connected” may be used to indicate that two or more elements are in direct physics or electrical contact with each other. “Coupled” may mean that two or more elements are either in direct physical or electrical contact or that two or more elements are not in direct contact with each other but yet still co-operate or interact with each other.

Configuration of the NVM Cell

The present invention provides a memory device capable of being embedded in a single-poly CMOS IC. In a preferred embodiment, P channel transistors under PMOS process allows programming and erasing to be accomplished at relatively low voltages, while reliably retaining stored charge.

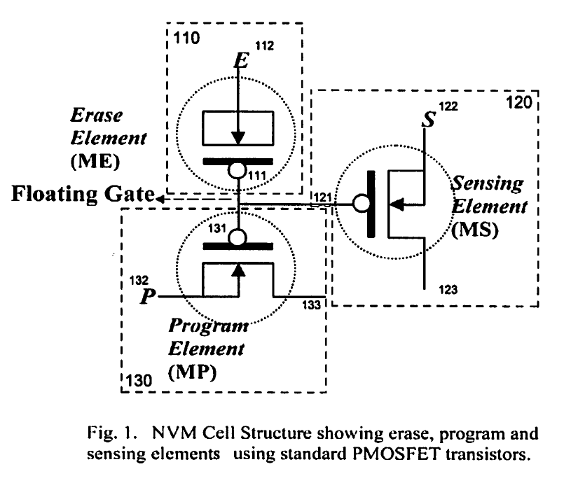

FIG. 1 is a chart showing an NVM Cell Structure 100 in accordance with the present invention. The NVM cell comprises three transistors, one as an erase element 110, one as a sensing element 120, and another one as a program element 130. All these elements may be embodied as normal MOSFET transistors, making the NVM cell fully compatible with industry CMOS processing, and preferably be embodied as PMOSFET transistors for lower application voltage as noted above. However, the invention is not so limited, and any appropriate element may be used. The descriptions below will be made in the context of PMOSFETs.

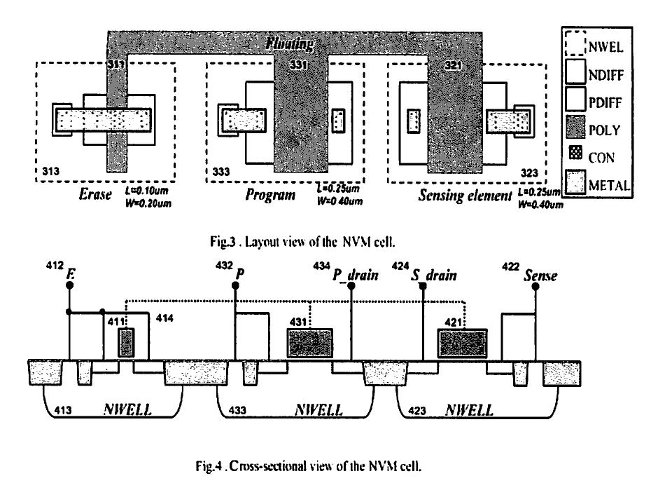

As shown, each of the PMOSFETs has a drain (414, 424, 434 in FIG. 4), a gate (411, 421, 431 in FIG. 4) and a source (412, 422, 432 in FIG. 4), and their gate poly-silicon layers are capacitively coupled to serve as floating gate (FG) for charge storage. Further more, the source 132 of the program element 130 serves as a program terminal (represented as the P terminal), the source 122 of the sensing element 123 serves as a sensing terminal (represented as the S terminal), and the source and drain of the erase element 110 are connected together as an erase terminal (represented as the E terminal). The present invention obtains many advantages from such a configuration. For example, by having individual program element, erase element and sensing element, the program, erase and read operations each can be optimized for performance, power consumption and reliability, which will be described in more details below. Additionally, since the sensing transistor only shares the floating gate with the program and erase elements, the outside sensing circuitry can be made simply without any high voltage supply, so as to achieve a simple read mechanism. Any high voltage (for example, higher than voltage supply V_{cc}) is only needed for program and erase elements. This will make low voltage read operation possible.

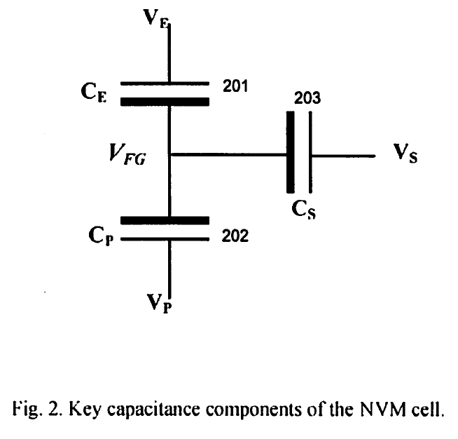

FIG. 2 shows the key capacitance components of the NVM cell in accordance with the present invention. The key capacitance components of the NVM cell include a C_{E} 201, a C_{P} 202 and a C_{S} 203, with an erase voltage V_{E} applied on the C_{E} 201, a program voltage V_{P} applied on the C_{P} 202, and a sensing voltage V_{S} applied on the C_{S} 203.

The simplified top view layout and the cross-sectional view of the NVM cell in accordance with the present invention are shown in FIG. 3 and FIG. 4, respectively. It can be seen from the Figures that, each PMOSFET transistor resides in separate NWELLs (313, 323 and 333 in FIG. 3; 413, 423, and 433 in FIG. 4) for independent control over NWELL biases in program, erase and read operations, thereby the reliability of the NVM cell is improved. The erase element 310, the sensing element 320 and the program element 330 have their floating gate (poly-silicon layer 311, 321 and 331) coupled. So the potential on the shared floating gate is capacitively coupled from program terminal, erase terminal, and sensing terminal. These gates may be formed from any suitable material, and preferably, all three PMOSFET transistors may have same gate oxide. To be completely compatible with the CMOS process, the thickness of the gate oxide may be in the range of 60-80 Å, which is the same thickness in I/O transistors used in, for example, 0.13 μm CMOS process. Therefore, no additional mask or process steps are added in the manufacture of the NVM of the present invention. As will be appreciated by the skilled in the art, other thickness is also possible, depending on different processes and application demands.

In FIG. 3, just by means of an example, the erase element is shown with a length of 0.10 μm and a width of 0.20 μm, while the program and sensing element with the same length of 0.25 μm and the same width of 0.40 μm. However, the length and width of each transistor can be chosen to have the best performance and also allow lower voltage program/erase than conventional Flash technology. The rules for choosing transistor length and width are known to those skilled in the art, and will not be described herein. As shown in the Figures, the program element and the sensing element may be substantially symmetrically positioned.

Further more, in one embodiment of the present invention, as it can be seen from FIG. 3, the gate oxide area of the erase PMOS may be much smaller than that of the program PMOS and that of the sensing PMOS, respectively. In doing so, the voltage applied for erase operation may be further reduced to be adapted for low voltage applications, which will be described below.

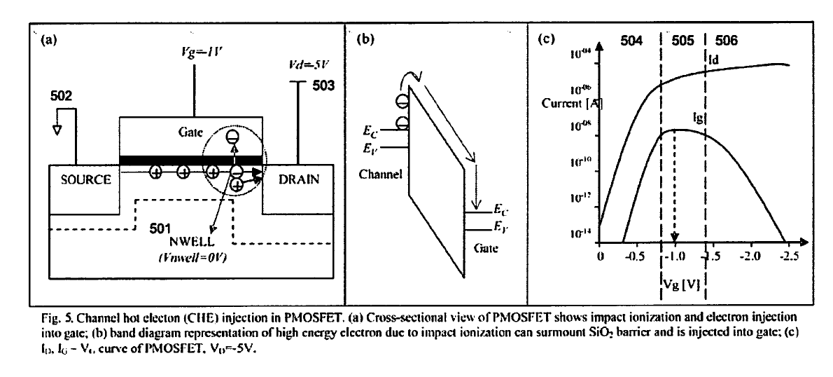

The program, the read and the erase operation of the NVM cell according to the present invention will be described below by referring to FIGS. 5a to 5b. In the following description, numerous details are set forth. It will be apparent, however, to one skilled in the art, that the present invention may be practiced without these specific details. Indeed, those skilled in the art having the benefit of this disclosure will appreciate that many other variations from the description and drawings may be made within the scope of the present inventions.

Programming Operation

Just as an example, the Channel hot electron (CHE) injection mechanism is an excellent choice for the NVM cell programming. Referring to FIG. 5a, when a large drain bias applied to the program PMOSFET, minority carriers, holes, flowing in the channel are heated up closer to the drain under large lateral field. This leads to impact ionization process and creates electron and hole pairs. These generated electrons and holes are highly energetic. Electrons are mostly collected at the NWELL 501 (substrate), and holes are collected at the drain 503.

When the oxide electric field favors electron injection, some of the electrons that have enough energy will surmount the Si/SiO₂ barrier and become gate current. This phenomenon is shown in FIG. 5a and 5b. Typical drain current I_{d}, gate current I_{g} to gate voltage V_{g} curves are shown in FIG. 5c. As will be seen from the FIG. 5c, when |V_{g}| starts to increase from 0V, both of I_{g} and I_{d} increase under a sub-threshold conduction, as shown in region 504. I_{g} reaches peak when |V_{g}| is slightly larger than the threshold voltage V_{T} of PMOSFET. When |V_{g}| further increases, I_{d} will not increase significantly as the program transistor is operating in the saturation region, as shown in region 505. The pinchoff region moves away from the drain 503, and then the lateral electric field become smaller. Therefore, I_{g} decreases with further increasing |V_{g}|, as shown in region 506.

To program the NVM cell, a program voltage in the range of 3V-6V, for example 5V, is applied on the NWELL/source (for example, the P terminal 132 in FIG. 1) of the program PMOSFET, with the drain at ground. Floating gate is capacitively coupled to a voltage for example of 4V (so V_{GB}=−1V). The skilled in the art will understand that CHE programming in PMOSFET can be done at lower drain current compared to CHE NMOSFET. Programming efficiency, ratio of I_{g} and I_{d} is also higher (>10⁻⁴).

The programming process is self-convergence. With electrons are injected into floating gate, V_{FG} becomes lower and V_{GB} becomes higher. Hence I_{g} reduces and programming of the cell is achieved. Typical programming time in this embodiment is expected to be 1-20 uSec.

Although the program process is described to be performed by the Channel hot electron (CHE) injection mechanism, the present invention is not limited in this aspect. Other suitable mechanisms may also be applied. For example, Band-to-Band-tunneling induced Hot Electron injection (BBHE), Source Side Injection (SSI) and Fowler-Nordheim tunneling (FN) may also be used for the program process in the present invention.

Erase Operation

In one embodiment of the present invention, the erase may be done with Fowler-Nordheim (FN) Tunneling through the erase PMOSFET. Fowler-Nordheim tunneling—also called Field emission—is the process whereby electrons tunnel through a barrier in the presence of a high electric field. This quantum mechanical tunneling process is an important mechanism for thin barriers as those in metal-semiconductor junctions on highly-doped semiconductors.

As to do the erase operation, an erase voltage in the range of 6V to 9V, for example 7V, is applied to the NWELL/Diffusion of the erase PMOSFET, while all other terminals of the NVM cell are grounded. As noted above, since the gate oxide area of the erase PMOSFET is much smaller than that of the program PMOSFET and that of the sensing PMOSFET, the floating gate potential is thus held close to 0V. Therefore, a large oxide field (˜7V) is present in the erase PMOSFET, whereby the erase operation is achieved.

As mentioned above, although the erase process is described to be performed by the Fowler-Nordheim Tunneling mechanism, the present invention is not limited in this aspect. Other suitable mechanisms may also be applied. For example, Band-to-Band-tunneling induced Hot Hole injection (BBHH), Channel Hot Hole (CHH) injection may also be used for the erase process in the present invention.

Read Operation

Sensing is done through the sensing PMOSFET. Since its gate is connected with the floating gate, its gate potential is determined by the state of the NVM cell. By employing the configuration of the present invention as described referring to FIGS. 14, the sensing scheme may be largely simplified, and the read time is reduced.

When NVM cell is in its native state with Q_{FG}=0, V_{FG}=V_{CC}/2. When the NVM cell is programmed (Q_{FG}<0), V_{FG} becomes higher, then sensing PMOSFET is less conductive. When the NVM cell is erased (Q_{FG}>0), VFG becomes lower, then sensing PMOSFET becomes more conductive. Fast read time, a few nSec, is expected owing to the simple sensing scheme.

Again, the present invention is not limited to the described sensing scheme, other technologies such as using NMOSFET as the sensing transistor, or using depletion-mode PMOSFET as the sensing transistor may also be applicable.

An example of the operating voltages are shown in the table below (table 1), in order to help understanding the above described operation mechanisms.

TABLE 1

| | | Program | | Sensing | | |
|---|---|---|---|---|---|---|
| Cell | Erase Element | element | | element | | |
| Operation | E | P | P_drain | Sense | S_drain | VFG |
| Program | 5 | 5 | 0 | Vcc | Vcc | ~4 V |
| Erase | 7 | 0 | 0 | 0 | 0 | 0 V |
| Read | 0 | 0 | 0 | Vcc | 0 | ~Vcc/2 |

While the above is a complete description of specific embodiments of the present invention, various modifications, variations, and alternatives may be employed. For example, the recited voltage levels could be varied to accommodate different design rules (circuit dimensions). These equivalents and alternatives are intended to be included within the scope of the present invention. Therefore, the scope of this invention should not be limited to the embodiments described, and should instead be defined by the following claims.

What is claimed is:

1. A single-poly non-volatile memory cell comprising:
a program transistor with a program terminal;
a sensing transistor with a sensing terminal; and
an erase transistor with an erase terminal,
wherein the sensing transistor shares a floating gate with the program transistor and the erase transistor.

2. The single-poly non-volatile memory cell as recited in claim 1, wherein the gate area of the erase transistor is much smaller than that of the program transistor and that of the sensing transistor, respectively.

3. The single-poly non-volatile memory cell as recited in claim 1, wherein the program transistor, the sensing transistor and the erase transistor are PMOSFETs.

4. The single-poly non-volatile memory cell as recited in claim 1, wherein each of the program transistor, the sensing transistor and the erase transistor reside in three separate NWELLs.

5. The single-poly non-volatile memory cell as recited in claim 1, wherein the program transistor, the sensing transistor and the erase transistor have a substantially same gate oxide thickness in the range of 60-80 Å.

6. The single-poly non-volatile memory cell as recited in claim 1, wherein the potential on the shared floating gate is capacitively coupled from the program terminal, the erase terminal, and the sensing terminal.

7. The single-poly non-volatile memory cell as recited in claim 1, wherein the single-poly non-volatile memory cell is constructed with single poly-silicon.

8. A single-poly non-volatile storage device, comprising:
a plurality of cells, each cell comprising:
a program transistor with a program terminal,
a sensing transistor with a sensing terminal, and
an erase transistor with an erase terminal,
wherein the sensing transistor shares a floating gate with the program transistor and the erase transistor.

9. The single-poly non-volatile memory device as recited in claim 8, wherein the gate area of the erase transistor is much smaller than that of the program transistor and that of the sensing transistor, respectively.

10. The single-poly non-volatile memory device as recited in claim 8, wherein the program transistor, the sensing transistor and the erase transistor are PMOSFETs.

11. The single-poly non-volatile memory device as recited in claim 8, wherein the program transistor, the sensing transistor and the erase transistor reside on three separate NWELLs.

12. The single-poly non-volatile memory device as recited in claim 8, wherein the program transistor, the sensing transistor and the erase transistor have the same gate oxide thickness in the range of 60-80 Å.

13. The single-poly non-volatile memory device as recited in claim 8, wherein the potential on the shared floating gate is capacitively coupled to the program terminal, the erase terminal, and the sensing terminal.

14. The single-poly non-volatile memory device as recited in claim 8, wherein each of the cells is constructed with single poly-silicon.

15. The single-poly non-volatile memory device as recited in claim 8, further comprising:
a program mechanism;
an erase mechanism; and
a read mechanism.

16. The single-poly non-volatile memory device as recited in claim 15, wherein the program mechanism functions by applying a first voltage on the program terminal, wherein the first voltage is not higher than 5V.

17. The single-poly non-volatile memory device as recited in claim 15, wherein the erase mechanism functions by applying a second voltage on the erase terminal, wherein the second voltage is not higher than 7V.

18. The single-poly non-volatile memory device as recited in claim 15, wherein the read mechanism functions without any external high voltage supply.

19. The single-poly non-volatile memory device as recited in claim 15, wherein the program mechanism functions by Channel Hot Electron (CHE) Injection.

20. The single-poly non-volatile memory device as recited in claim 15, wherein the erase mechanism functions by Fowler-Nordheim (FN) Tunneling.
